(19) United States
(12) Patent Application Publication
(10) Pub. No.: US 2026/0031815 A1
(43) Pub. Date: Jan. 29, 2026

(54) CLOCK BUFFER CIRCUIT AND A SEMICONDUCTOR APPARATUS USING THE CLOCK BUFFER CIRCUIT

(71) Applicant: SK hynix Inc., Icheon-si Gyeonggi-do (KR)

(72) Inventor: Sung Phil CHOI, Icheon-si Gyeonggi-do (KR)

(73) Assignee: SK hynix Inc., Icheon-si Gyeonggi-do (KR)

(21) Appl. No.: 18/956,966

(22) Filed: Nov. 22, 2024

(30) Foreign Application Priority Data
Jul. 29, 2024 (KR) 10-2024-0100275

(51) Int. Cl. H03K 19/0185; G06F 1/04; H03K 19/20

(52) U.S. Cl. CPC H03K 19/018521; G06F 1/04; H03K 19/20

(57) ABSTRACT

A clock buffer circuit includes a first clock driver and a second clock driver. The first clock driver is configured to receive a first input clock signal and an enable signal to generate a first output clock signal. The second clock driver is configured to receive a second input clock signal and the enable signal to generate a second output clock signal. A virtual node of the first clock driver and a virtual node of the second clock driver are electrically connected to each other.

### CROSS-REFERENCES TO RELATED APPLICATION

The present application claims priority under 35 U.S.C. § 119(a) to Korean application number 10-2024-0100275 filed on Jul. 29, 2024, in the Korean Intellectual Property Office, which application is incorporated herein by reference in its entirety.

### BACKGROUND

### 1. Technical Field

Various embodiments generally relate to integrated circuit technology, and, more particularly, to a clock buffer circuit and a semiconductor apparatus using the clock buffer circuit.

### 2. Related Art

A semiconductor apparatus may include a plurality of internal circuits, and the plurality of internal circuits may transmit and receive signals to and from each other. A buffer circuit and/or a repeater circuit may be used to transmit signals from one internal circuit to another internal circuit. Generally, the buffer circuit and/or repeater circuit may be implemented with a driver to drive an input signal, and a slight loss of signal may occur in a simple driver that drives an input signal to generate an output signal. However, a driver that includes activation control function, such as power-gating, should receive an activation control signal and/or an enable control signal along with an input signal. A driver that receives both a control signal and an input signal should include a structure that includes transistors connected in series. However, the slew rate of an output signal generated by a driver including transistors connected in series may be decreased. The decrease in the slew rate of a PRBS (Pseudo Random Binary Signal) may have little effect on the operation of an internal circuit receiving the PRBS signal, but a decrease in the slew rate of a signal, the logic level of which changes periodically, such as a clock signal, may cause a malfunction of a subsequent internal circuit.

### SUMMARY

In an embodiment, a clock buffer circuit may include a

first clock driver and a second clock driver. The first clock driver, including two transistors connected in series, may be configured to receive a first input clock signal and an enable signal to generate a first output clock signal, the two transistors of the first clock driver receiving the first input clock signal and the enable signal, respectively. The second clock driver, including two transistors connected in series, may be configured to receive a second input clock signal and the enable signal to generate a second output clock signal, the two transistors of the second clock driver receiving the first input clock signal and the enable signal, respectively. A node between the two transistors of the first clock driver and a node between the two transistors of the second clock driver may be electrically connected.

In an embodiment, a clock buffer circuit may include a first clock driver and a second clock driver. The first clock driver may be configured to receive a first input clock signal and an enable signal to generate a first output clock signal and may include a first virtual ground node. The second clock driver may be configured to receive a second input clock signal and the enable signal to generate a second output clock signal and may include a second virtual ground node. The first virtual ground node may be electrically connected to the second virtual ground node.

In an embodiment, a clock buffer circuit may include a first clock driver and a second clock driver. The first clock driver may be configured to receive a first input clock signal and an enable signal to generate a first output clock signal and may include a first virtual supply node. The second clock driver may be configured to receive a second input clock signal and the enable signal to generate a second output clock signal and may include a second virtual supply node. The first virtual supply node may be electrically connected to the second virtual supply node.

In an embodiment, a semiconductor apparatus may include a first clock driver, a second clock driver, a first data receiver, and a second data receiver. The first clock driver may be configured to receive a first input clock signal and an enable signal to generate a first output clock signal and may include a first virtual node. The second clock driver may be configured to receive a second input clock signal and the enable signal to generate a second output clock signal and may include a second virtual node electrically connected to the first virtual node. The first data receiver may be configured to receive a data signal in synchronization with the first output clock signal to generate a first internal data signal. The second data receiver may be configured to receive the data signal in synchronization with the second output clock signal to generate a second internal data signal.

### BRIEF DESCRIPTION OF THE DRAWINGS

FIG. 1 is a diagram illustrating a configuration of a clock buffer circuit according to an embodiment of the present disclosure.

FIG. 2 is a circuit diagram illustrating a configuration of a clock buffer circuit according to an embodiment of the present disclosure.

FIG. 3A is a timing diagram illustrating an operation of a conventional clock buffer circuit, and FIG. 3B is a timing diagram illustrating an operation of a clock buffer circuit according to an embodiment of the present disclosure.

FIG. 4 is a circuit diagram illustrating a configuration of a clock buffer circuit according to an embodiment of the present disclosure.

FIG. 5A is a timing diagram illustrating an operation of a conventional clock buffer circuit, and FIG. 5B is a timing diagram illustrating an operation of a clock buffer circuit according to an embodiment of the present disclosure.

FIG. 6 is a diagram illustrating a configuration of a semiconductor apparatus according to an embodiment of the present disclosure.

FIG. 7 is a diagram illustrating a configuration of a clock buffer circuit according to an embodiment of the present disclosure.

FIG. 8 is a circuit diagram illustrating a configuration of a clock buffer circuit according to an embodiment of the present disclosure.

FIG. 9 is a circuit diagram illustrating a configuration of a clock buffer circuit according to an embodiment of the present disclosure.

FIG. 10 is a diagram illustrating a configuration of a semiconductor apparatus according to an embodiment of the present disclosure.

### DETAILED DESCRIPTION

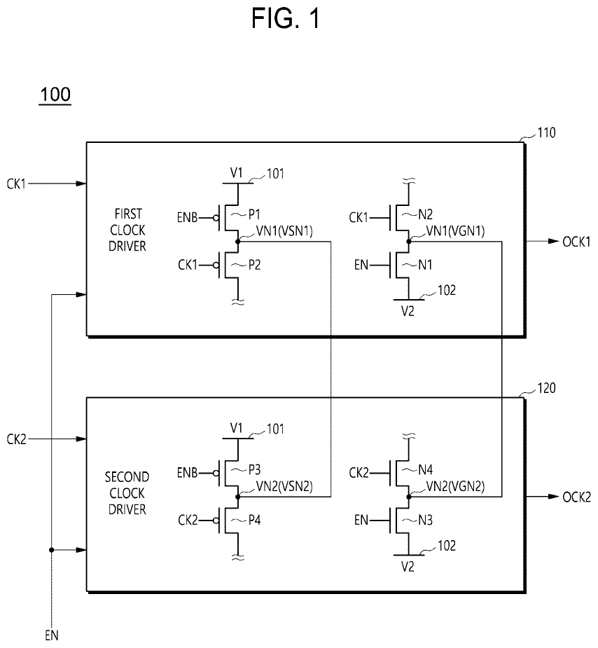

FIG. 1 is a diagram illustrating a configuration of a clock buffer circuit 100 according to an embodiment of the present disclosure. Referring to FIG. 1, the clock buffer circuit 100 may receive a first input clock signal CK1 and a second input clock signal CK2 to generate a first output clock signal OCK1 and a second output clock signal OCK2. The clock buffer circuit 100 may buffer, drive, or repeat the first and second input clock signals CK1 and CK2 to generate the first and second output clock signals OCK1 and OCK2. The clock buffer circuit 100 may buffer, drive, and/or repeat the first input clock signal CK1 to generate the first output clock signal OCK1 and may buffer, drive, and/or repeat the second input clock signal CK2 to generate the second output clock signal OCK2. The second input clock signal CK2 may have a different phase compared to the first input clock signal CK1. The second input clock signal CK2 may have a lagging phase of 90 degrees, 180 degrees, or 270 degrees relative to the first input clock signal CK1. For example, the clock buffer circuit 100 may receive a half-rate clock signal, and the second input clock signal CK2 may have a lagging phase of 180 degrees relative to the first input clock signal CK1. The phase relationship between the first and second output clock signals OCK1 and OCK2 may be substantially the same as the phase relationship between the first and second input clock signals CK1 and CK2.

The clock buffer circuit 100 may further receive an enable signal EN. The enable signal EN may be a signal that can selectively enable the clock buffer circuit 100. For example, the enable signal EN may be a signal for power-gating the clock buffer circuit 100. When the enable signal EN is enabled, the clock buffer circuit 100 may be activated and may generate the first and second output clock signals OCK1 and OCK2 from the first and second input clock signals CK1 and CK2. When the enable signal EN is disabled, the clock buffer circuit 100 may be disabled and might not generate the first and second output clock signals OCK1 and OCK2. The clock buffer circuit 100 may mitigate the decrease in the slew rate of the first and second output clock signals OCK1 and OCK2 as the clock buffer circuit 100 is power-gated by the enable signal EN. The clock buffer circuit 100 may improve the slew rate of the first and second output clock signals OCK1 and OCK2. The slew rate may be related to a rising time and a falling time of the first and second output clock signals OCK1 and OCK2, and the rising time and the falling time may be related to a transition slope of a rising edge and a falling edge. As the slew rate increases, the rising time and the falling time may decrease, and the transition slope of the rising edge and the falling edge may steepen. For example, the clock buffer circuit 100 may decrease the falling times of the first and second output clock signals OCK1 and OCK2 and may steepen the transition slopes of falling edges. In an embodiment, the clock buffer circuit 100 may decrease the rising times of the first and second output clock signals OCK1 and OCK2 and may steepen the transition slopes of rising edges.

The clock buffer circuit 100 may include a first clock driver 110 and a second clock driver 120. The first clock driver 110 may receive the first input clock signal CK1 and the enable signal EN to generate the first output clock signal OCK1. When the enable signal EN is enabled, the first clock driver 110 may buffer, drive, and/or repeat the first input clock signal CK1 to generate the first output clock signal OCK1. When the enable signal EN is disabled, the first clock driver 110 may be disabled and might not generate the first output clock signal OCK1 from the first input clock signal CK1.

The second clock driver 120 may receive the second input clock signal CK2 and the enable signal EN to generate the second output clock signal OCK2. When the enable signal EN is enabled, the second clock driver 120 may buffer, drive, and/or repeat the second input clock signal CK2 to generate the second output clock signal OCK2. When the enable signal EN is disabled, the second clock driver 120 may be disabled and might not generate the second output clock signal OCK2 from the second input clock signal CK2.

The first and second clock drivers 110 and 120 may include any driver circuit capable of buffering, driving, and/or repeating a received input clock signal. The second clock driver 120 may have substantially the same structure as the first clock driver 110. The first and second clock drivers 110 and 120 may each include two transistors connected in series. The two transistors of the first and second clock drivers 110 and 120 may both be the same type of transistor. A node between the two transistors of the first clock driver 110 may be electrically connected to a node between the two transistors of the second clock driver 120. The node between the two transistors of the first clock driver 110 may be a first virtual node. The node between the two transistors of the second clock driver 120 may be a second virtual node. The two transistors of the first clock driver 110 may receive the first input clock signal CK1 and the enable signal EN, respectively. The two transistors of the second clock driver 120 may receive the second input clock signal CK2 and the enable signal EN, respectively.

In an embodiment, the first clock driver 110 may include a first PMOS transistor P1 and a second PMOS transistor P2, and the second clock driver 120 may include a third PMOS transistor P3 and a fourth PMOS transistor P4. A gate of the first PMOS transistor P1 may receive an enable signal ENB. The enable signal ENB may be a complementary signal and/or an inverted signal of the enable signal EN. A source of the first PMOS transistor P1 may be electrically connected to a first voltage terminal 101 to which a first voltage V1 is supplied. The first voltage V1 may have a sufficiently high voltage level to be determined as a high logic level. For example, the first voltage V1 may be a power supply voltage of a semiconductor apparatus including the clock buffer circuit 100. A gate of the second PMOS transistor P2 may receive the first input clock signal CK1. A source of the second PMOS transistor P2 may be electrically connected to a drain of the first PMOS transistor P1. A drain of the second PMOS transistor P2 may be electrically connected to another transistor of the first clock driver 110. A node to which the drain of the first PMOS transistor P1 and the source of the second PMOS transistor P2 are connected may be the first virtual node VN1 of the first clock driver 110. A gate of the third PMOS transistor P3 may receive the enable signal ENB. A source of the third PMOS transistor P3 may be electrically connected to the first voltage terminal 101. A gate of the fourth PMOS transistor P4 may receive the second input clock signal CK2. A source of the fourth PMOS transistor P4 may be electrically connected to a drain of the third PMOS transistor P3. A drain of the fourth PMOS transistor P4 may be electrically connected to another transistor of the second clock driver 120. A node to which the drain of the third PMOS transistor P3 and the source of the fourth PMOS transistor P4 are connected may be the second virtual node VN2 of the second clock driver 120. When the enable signal ENB is enabled to a low logic level, the first and third PMOS transistors P1, P3 may be turned on and may supply the first voltage V1 to the first and second virtual nodes VN1 and VN2, respectively. Accordingly, the first virtual node VN1 may be a first virtual supply node VSN1, and the second virtual node VN2 may be a second virtual supply node VSN2. When the first virtual supply node VSN1 and the second virtual supply node VSN2 are electrically connected, the rising times of the first and second output clock signals OCK1 and OCK2 may be decreased and the transition slopes of rising edges may become steeper to mitigate the decrease in the slew rate of the first and second output clock signals OCK1 and OCK2.

In an embodiment, the first clock driver 110 may include a first NMOS transistor N1 and a second NMOS transistor N2, and the second clock driver 120 may include a third NMOS transistor N3 and a fourth NMOS transistor N4. A gate of the first NMOS transistor N1 may receive the enable signal EN. A source of the first NMOS transistor N1 may be electrically connected to a second voltage terminal 102 to which a second voltage V2 is supplied. The second voltage V2 may have a lower voltage level than the first voltage V1. The second voltage V2 may have a sufficiently low voltage level to be determined as a low logic level. For example, the second voltage V2 may be a ground voltage. A gate of the second NMOS transistor N2 may receive the first input clock signal CK1. A source of the second NMOS transistor N2 may be electrically connected to a drain of the first NMOS transistor N1. A drain of the second NMOS transistor N2 may be electrically connected to another transistor of the first clock driver 110. A node to which the drain of the first NMOS transistor N1 and the source of the second NMOS transistor N2 are connected may be a first virtual node VN1 of the first clock driver 110. A gate of the third NMOS transistor N3 may receive the enable signal EN. A source of the third NMOS transistor N3 may be electrically connected to the second voltage terminal 102. A gate of the fourth NMOS transistor N4 may receive the second input clock signal CK2. A source of the fourth NMOS transistor N4 may be electrically connected to a drain of the third NMOS transistor N3. A drain of the fourth NMOS transistor N4 may be electrically connected to another transistor of the second clock driver 120. A node to which the drain of the third NMOS transistor N3 and the source of the fourth NMOS transistor N4 are connected may be a second virtual node VN2 of the second clock driver 120. When the enable signal EN is enabled to a high logic level, the first and third NMOS transistors N1 and N3 may be turned on and may supply the second voltage V2 to the first and second virtual nodes VN1 and VN2, respectively. Accordingly, the first virtual node VN1 may be a first virtual ground node VGN1, and the second virtual node VN2 may be a second virtual ground node VGN2. When the first virtual ground node VGN1 and the second virtual ground node VGN2 are electrically connected, falling times of the first and second output clock signals OCK1 and OCK2 may be decreased and transition slopes of falling edges may become steeper to mitigate or to avoid the decrease in the slew rate of the first and second output clock signals OCK1 and OCK2.

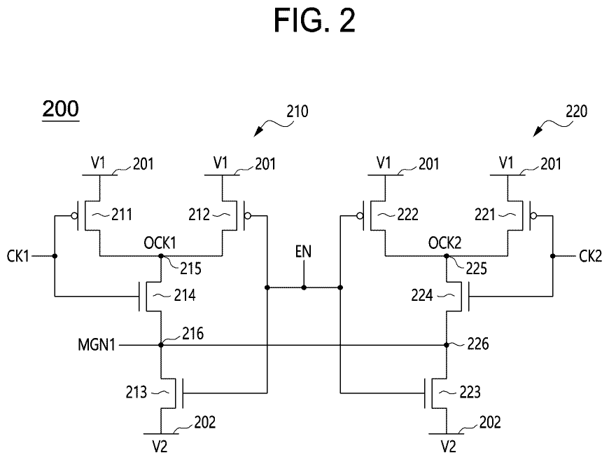

FIG. 2 is a circuit diagram illustrating a configuration of a clock buffer circuit 200 according to an embodiment of the present disclosure. Referring to FIG. 2, the clock buffer circuit 200 may include a first clock driver 210 and a second clock driver 220, and the first and second clock drivers 210 and 220 may each include a two-input NAND gate. The first and second clock drivers 210 and 220 may be applied as the first and second clock drivers 110 and 120 as shown in FIG. 1, respectively. The first clock driver 210 may receive the first input clock signal CK1 and the enable signal EN to generate the first output clock signal OCK1. The second clock driver 220 may receive the second input clock signal CK2 and the enable signal EN to generate the second output clock signal OCK2. The first clock driver 210 may include a first virtual ground node 216, and the second clock driver 220 may include a second virtual ground node 226. The first virtual ground node 216 may be electrically connected to the second virtual ground node 226. The first clock driver 210 may include two transistors connected in series, receiving the first input clock signal CK1 and the enable signal EN, respectively. The two transistors may be NMOS transistors. A node between the two transistors may be the first virtual ground node 216. The second clock driver 220 may include two transistors connected in series, receiving the second input clock signal CK2 and the enable signal EN, respectively. The two transistors may be NMOS transistors. A node between the two transistors may be the second virtual ground node 226.

The first clock driver 210 may include a first transistor 211, a second transistor 212, a third transistor 213, and a fourth transistor 214. The first and second transistors 211 and 212 may be PMOS transistors, and the third and fourth transistors 213 and 214 may be NMOS transistors. The first and second transistors 211 and 212 may be electrically connected in parallel between a first voltage terminal 201 to which the first voltage V1 is supplied and a first output node 215. The first output clock signal OCK1 may be output from the first output node 215. The first transistor 211 may receive the first input clock signal CK1 to electrically connect the first voltage terminal 201 to the first output node 215. A gate of the first transistor 211 may receive the first input clock signal CK1, a source of the first transistor 211 may be electrically connected to the first voltage terminal 201, and a drain of the first transistor 211 may be electrically connected to the first output node 215. The second transistor 212 may receive the enable signal EN to electrically connect the first voltage terminal 201 to the first output node 215. A gate of the second transistor 212 may receive the enable signal EN, a source of the second transistor 212 may be electrically connected to the first voltage terminal 201, and a drain of the second transistor 212 may be electrically connected to the first output node 215. The third and fourth transistors 213 and 214 may be connected in series between the first output node 215 and a second voltage terminal 202 to which the second voltage V2 is supplied. The third transistor 213 may receive the enable signal EN to electrically connect the first virtual ground node 216 to the second voltage terminal 202. A gate of the third transistor 213 may receive the enable signal EN, a drain of the third transistor 213 may be electrically connected to the first virtual ground node 216, and a source of the third transistor 213 may be electrically connected to the second voltage terminal 202. The fourth transistor 214 may receive the first input clock signal CK1 to electrically connect the first output node 215 to the first virtual ground node 216. A gate of the fourth transistor 214 may receive the first input clock signal CK1, a drain of the fourth transistor 214 may be electrically connected to the first output node 215, and a source of the fourth transistor 214 may be electrically connected to the first virtual ground node 216.

The second clock driver 220 may include a fifth transistor 221, a sixth transistor 222, a seventh transistor 223, and an eighth transistor 224. The fifth and sixth transistors 221 and 222 may be PMOS transistors, and the seventh and eighth transistors 223 and 224 may be NMOS transistors. The fifth and sixth transistors 221 and 222 may be electrically connected in parallel between the first voltage terminal 201 and a second output node 225. The second output clock signal OCK2 may be output from the second output node 225. The fifth transistor 221 may receive the second input clock signal CK2 to electrically connect the first voltage terminal 201 and the second output node 225. A gate of the fifth transistor 221 may receive the second input clock signal CK2, a source of the fifth transistor 221 may be electrically connected to the first voltage terminal 201, and a drain of the fifth transistor 221 may be electrically connected to the second output node 225. The sixth transistor 222 may receive the enable signal EN to electrically connect the first voltage terminal 201 to the second output node 225. A gate of the sixth transistor 222 may receive the enable signal EN, a source of the sixth transistor 222 may be electrically connected to the first voltage terminal 201, and a drain of the sixth transistor 222 may be electrically connected to the second output node 225. The seventh and eighth transistors 223, 224 may be connected in series between the second output node 225 and the second voltage terminal 202. The seventh transistor 223 may receive the enable signal EN to electrically connect the second virtual ground node 226 to the second voltage terminal 202. A gate of the seventh transistor 223 may receive the enable signal EN, a drain of the seventh transistor 223 may be electrically connected to the second virtual ground node 226, and a source of the seventh transistor 223 may be electrically connected to the second voltage terminal 202. The eighth transistor 224 may receive the second input clock signal CK2 to electrically connect the second output node 225 to the second virtual ground node 226. A gate of the eighth transistor 224 may receive the second input clock signal CK2, a drain of the eighth transistor 224 may be electrically connected to the second output node 225, and a source of the eighth transistor 224 may be electrically connected to the second virtual ground node 226. The second virtual ground node 226 may be electrically connected to the first virtual ground node 216, and the first and second virtual ground nodes 216 and 226 may be one merge node MGN1.

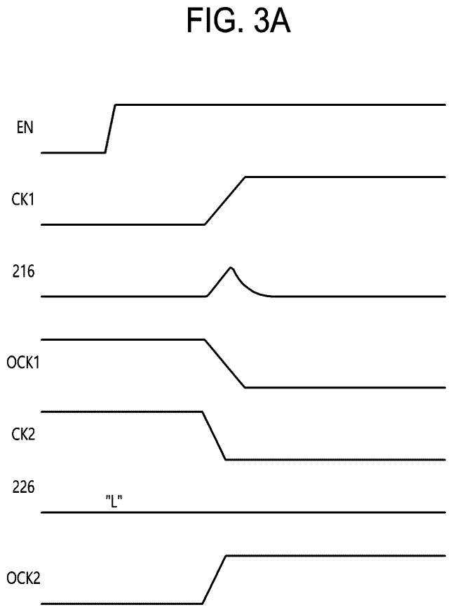

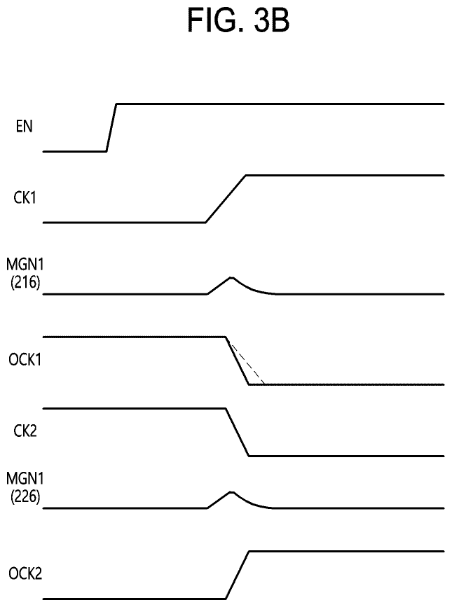

FIGS. 3A and 3B are timing diagrams illustrating an operation of the clock buffer circuit 200 according to an embodiment of the present disclosure. Referring to FIGS. 2, 3A, and 3B, the operation of the clock buffer circuit 200 according to an embodiment of the present disclosure will be described as follows. When the enable signal EN is disabled to a low logic level, the third and seventh transistors 213 and 223 are turned off, and the second voltage V2 might not be supplied to the first and second clock drivers 210 and 220. Accordingly, the first and second clock drivers 210 and 220 may be disabled. When the enable signal EN is enabled to a high logic level, the first and second clock drivers 210 and 220 may be enabled. When the enable signal EN is enabled to a high logic level, the second and sixth transistors 212 and 222 may be turned off, and the third and seventh transistors 213 and 223 may be turned on. The third transistor 213 may electrically connect the first virtual ground node 216 to the second voltage terminal 202, and the seventh transistor 223 may electrically connect the second virtual ground node 226 to the second voltage terminal 202. When the first input clock signal CK1 is at a low logic level and the second input clock signal CK2 is at a high logic level, the first transistor 211 may be turned on to generate the first output clock signal OCK1 having a high logic level, and the eighth transistor 224 may be turned on to generate the second output clock signal OCK2 having a low logic level. When the first input clock signal CK1 transitions from a low logic level to a high logic level and the second input clock signal CK2 transitions from a high logic level to a low logic level, the first transistor 211 may be turned off and the fourth transistor 214 may be turned on to drive the first output node 215 to a low logic level. Similarly, the eighth transistor 224 may be turned off and the fifth transistor 221 may be turned on so that the second output node 225 may be driven to a high logic level. As the first output node 215 is driven to a low logic level, the first output clock signal OCK1 may change from a high logic level to a low logic level. If the first virtual ground node 216 and the second virtual ground node 226 are not electrically connected, when the fourth transistor 214 is turned on, as shown in FIG. 3A, current may flow from the first output node 215 to the first virtual ground node 216, and a voltage level of the first virtual ground node 216 may temporarily rise. The temporary increase in a voltage level of the first virtual ground node 216 may increase the time required for the third transistor 213 to drive the first virtual ground node 216 to the second voltage V2 and may increase the time required for the first output clock signal OCK1 to transition from a high logic level to a low logic level. Thus, the slew rate of the first output clock signal OCK1 may be decreased. In the clock buffer circuit 200 according to an embodiment of the present disclosure, the first and second virtual ground nodes 216 and 226 may be electrically connected to each other and may become one merge node MGN1. When the first and second virtual ground nodes 216 and 226 are electrically connected, the merge node MGN1 may be driven to the second voltage V2 by the third and seventh transistors 213 and 223 together. Thus, when the fourth transistor 214 is turned on and current flows from the first output node 215 to the first virtual ground node 216, temporary increase in a voltage level of the first virtual ground node 216 can be mitigated, and falling time required for the first output clock signal OCK1 to transition from a high logic level to a low logic level can be decreased. In other words, the transition slope of the falling edge of the first output clock signal OCK1 may become steeper to mitigate the decrease in the slew rate of the first output clock signal OCK1. As shown in FIG. 3B, it can be seen that a transition slope of a falling edge of the first output clock signal OCK1 generated from the clock buffer circuit 200 is steeper than a transition slope (shown as a dotted line) of a falling edge of the first output clock signal OCK1 generated from the clock buffer circuit without the first and second virtual ground nodes connected. Although not shown, when the first input clock signal CK1 transitions from a high logic level to a low logic level and the second input clock signal CK2 transitions from a low logic level to a high logic level, falling time of the second output clock signal OCK2 can be decreased and a transition slope of a falling edge can be steeper to mitigate or to avoid a decrease in the slew rate of the second output clock signal OCK2.

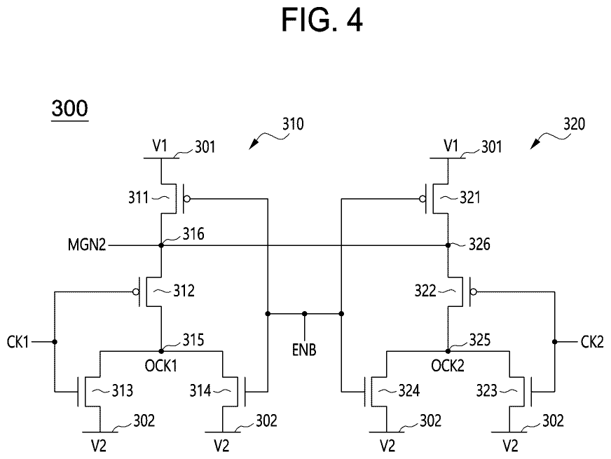

FIG. 4 is a diagram illustrating a configuration of a clock buffer circuit 300 according to an embodiment of the present disclosure. Referring to FIG. 4, the clock buffer circuit 300 may include a first clock driver 310 and a second clock driver 320, and the first and second clock drivers 310 and 320 may each include a two-input NOR gate. The first and second clock drivers 310 and 320 may be applied as the first and second clock drivers 110 and 120 as shown in FIG. 1, respectively. The first clock driver 310 may receive the first input clock signal CK1 and the enable signal ENB to generate the first output clock signal OCK1. The second clock driver 320 may receive the second input clock signal CK2 and the enable signal ENB to generate the second output clock signal OCK2. The first clock driver 310 may include a first virtual supply node 316, and the second clock driver 320 may include a second virtual supply node 326. The first virtual supply node 316 may be electrically connected to the second virtual supply node 326. The first clock driver 310 may include two transistors connected in series, receiving the first input clock signal CK1 and the enable signal ENB, respectively. The two transistors may be PMOS transistors. A node between the two transistors may be the first virtual supply node 316. The second clock driver 320 may include two transistors connected in series, receiving the second input clock signal CK2 and the enable signal ENB, respectively. The two transistors may be PMOS transistors. A node between the two transistors may be the second virtual supply node 326.

The first clock driver 310 may include a first transistor 311, a second transistor 312, a third transistor 313, and a fourth transistor 314. The first and second transistors 311 and 312 may be PMOS transistors, and the third and fourth transistors 313 and 314 may be NMOS transistors. The first and second transistors 311 and 312 may be connected in series between a first voltage terminal 301 to which the first voltage V1 is supplied and a first output node 315. The first output clock signal OCK1 may be output from the first output node 315. The first transistor 311 may receive the enable signal ENB to electrically connect the first voltage terminal 301 to the first virtual supply node 316. A gate of the first transistor 311 may receive the enable signal ENB, a source of the first transistor 311 may be electrically connected to the first voltage terminal 301, and a drain of the first transistor 311 may be electrically connected to the first virtual supply node 316. The second transistor 312 may receive the first input clock signal CK1 to electrically connect the first virtual supply node 316 to the first output node 315. A gate of the second transistor 312 may receive the first input clock signal CK1, a source of the second transistor 312 may be electrically connected to the first virtual supply node 316, and a drain of the second transistor 312 may be electrically connected to the first output node 315. The third and fourth transistors 313 and 314 may be electrically connected in parallel between the first output node 315 and a second voltage terminal 302 to which the second voltage V2 is supplied. The third transistor 313 may receive the first input clock signal CK1 to electrically connect the first output node 315 to the second voltage terminal 302. A gate of the third transistor 313 may receive the first input clock signal CK1, a drain of the third transistor 313 may be electrically connected to the first output node 315, and a source of the third transistor 313 may be electrically connected to the second voltage terminal 302. The fourth transistor 314 may receive the enable signal ENB to electrically connect the first output node 315 and the second voltage terminal 302. A gate of the fourth transistor 314 may receive the enable signal ENB, a drain of the fourth transistor 314 may be electrically connected to the first output node 315, and a source of the fourth transistor 314 may be electrically connected to the second voltage terminal 302.

The second clock driver 320 may include a fifth transistor 321, a sixth transistor 322, a seventh transistor 323, and an eighth transistor 324. The fifth and sixth transistors 321 and 322 may be PMOS transistors, and the seventh and eighth transistors 323 and 324 may be NMOS transistors. The fifth and sixth transistors 321 and 322 may be connected in series between the first voltage terminal 301 and a second output node 325. The second output clock signal OCK2 may be output from the second output node 325. The fifth transistor 321 may receive the enable signal ENB to electrically connect the first voltage terminal 301 to the second virtual supply node 326. A gate of the fifth transistor 321 may receive the enable signal ENB, a source of the fifth transistor 321 may be electrically connected to the first voltage terminal 301, and a drain of the fifth transistor 321 may be electrically connected to the second virtual supply node 326. The sixth transistor 322 may receive the second input clock signal CK2 to electrically connect the second virtual supply node 326 to the second output node 325. A gate of the sixth transistor 322 may receive the second input clock signal CK2, a source of the sixth transistor 322 may be electrically connected to the second virtual supply node 326, and a drain of the sixth transistor 322 may be electrically connected to the second output node 325. The seventh and eighth transistors 323 and 324 may be electrically connected in parallel between the second output node 325 and the second voltage terminal 302. The seventh transistor 323 may receive the second input clock signal CK2 to electrically connect the second output node 325 to the second voltage terminal 302. A gate of the seventh transistor 323 may receive the second input clock signal CK2, a drain of the seventh transistor 323 may be electrically connected to the second output node 325, and a source of the seventh transistor 323 may be electrically connected to the second voltage terminal 302. The eighth transistor 324 may receive the enable signal ENB to electrically connect the second output node 325 to the second voltage terminal 302. A gate of the eighth transistor 324 may receive the enable signal ENB, a drain of the eighth transistor 324 may be electrically connected to the second output node 325, and a source of the eighth transistor 324 may be electrically connected to the second voltage terminal 302. The second virtual supply node 326 may be electrically connected to the first virtual supply node 316, and the first and second virtual supply nodes 316 and 326 may be one merge node MGN2.

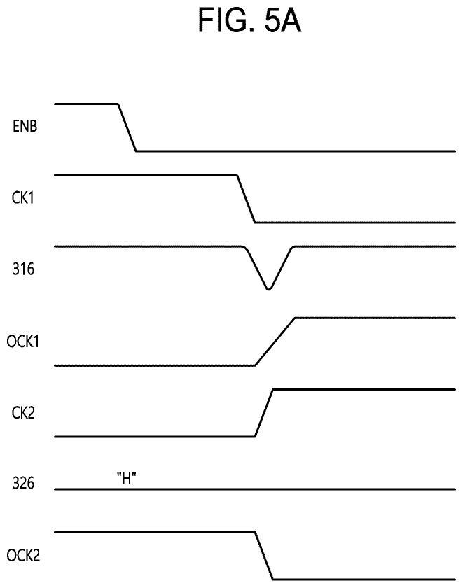

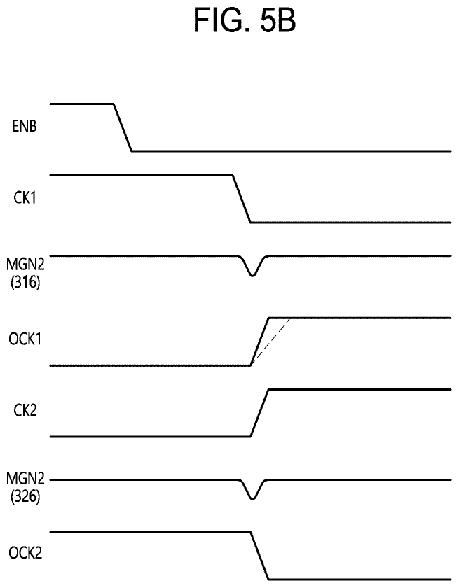

FIGS. 5A and 5B are timing diagrams illustrating an operation of the clock buffer circuit 300 according to an embodiment of the present disclosure. Referring to FIG. 4, FIG. 5A, and FIG. 5B, the operation of the clock buffer circuit 300 according to an embodiment of the present disclosure will be described as follows. When the enable signal ENB is disabled to a high logic level, the first and fifth transistors 311 and 321 may be turned off, and the first voltage V1 might not be supplied to the first and second clock drivers 310 and 320. Accordingly, the first and second clock drivers 310 and 320 may be disabled. When the enable signal ENB is enabled to a low logic level, the first and second clock drivers 310 and 320 may be enabled. When the enable signal ENB is enabled to a low logic level, the fourth and eighth transistors 314 and 324 may be turned off, and the first and fifth transistors 311 and 321 may be turned on. The first transistor 311 may electrically connect the first virtual supply node 316 to the first voltage terminal 301, and the fifth transistor 321 may electrically connect the second virtual supply node 326 to the first voltage terminal 301. When the first input clock signal CK1 is at a high logic level and the second input clock signal CK2 is at a low logic level, the third transistor 313 may be turned on to generate the first output clock signal OCK1 having a low logic level, and the sixth transistor 322 may be turned on to generate the second output clock signal OCK2 having a high logic level. When the first input clock signal CK1 transitions from a high logic level to a low logic level and the second input clock signal CK2 transitions from a low logic level to a high logic level, the third transistor 313 may be turned off and the second transistor 312 may be turned on to drive the first output node 315 to a high logic level. Similarly, the sixth transistor 322 may be turned off, and the seventh transistor 323 may be turned on, causing the second output node 325 to be driven to a low logic level. As the first output node 315 is driven to a high logic level, the first output clock signal OCK1 may change from a low logic level to a high logic level. If the first virtual supply node 316 and the second virtual supply node 326 are not electrically connected, then, when the second transistor 312 is turned on, as shown in FIG. 5A, current may flow from the first virtual supply node 316 to the first output node 315 and a voltage level of the first virtual supply node 316 may temporarily drop. The temporary drop in a voltage level of the first virtual supply node 316 may increase the time required for the first transistor 311 to drive the first virtual supply node 316 to the first voltage V1 and may increase the time required for the first output clock signal OCK1 to transition from a low logic level to a high logic level. Thus, the slew rate of the first output clock signal OCK1 may be decreased. In the clock buffer circuit 300, the first and second virtual supply nodes 316 and 326 may be electrically connected to each other and may become a single merge node MGN2. When the first and second virtual supply nodes 316 and 326 are electrically connected, the merge node MGN2 may be driven to the first voltage V1 by the first and fifth transistors 311 and 321 together. Thus, when the second transistor 312 is turned on to allow current to flow from the first virtual supply node 316 to the first output node, the temporary drop in a voltage level of the first virtual supply node 316 can be mitigated, and the rising time required for the first output clock signal OCK1 to transition from a low logic level to a high logic level can be decreased. In other words, the transition slope of the rising edge of the first output clock signal OCK1 may become steeper to mitigate or avoid the decrease in the slew rate of the first output clock signal OCK1. As shown in FIG. 5B, a transition slope of a rising edge of the first output clock signal OCK1 generated from the clock buffer circuit 300 becomes steeper than a transition slope (shown as a dashed line) of a rising edge of the first output clock signal OCK1 generated from the clock buffer circuit without the first and second virtual supply nodes 316 and 326 connected. Although not shown, when the first input clock signal CK1 transitions from a low logic level to a high logic level and the second input clock signal CK2 transitions from a high logic level to a low logic level, the rising time of the second output clock signal OCK2 can be decreased and a transition slope of a rising edge can become steeper to mitigate or to avoid a decrease in the slew rate of the second output clock signal OCK2.

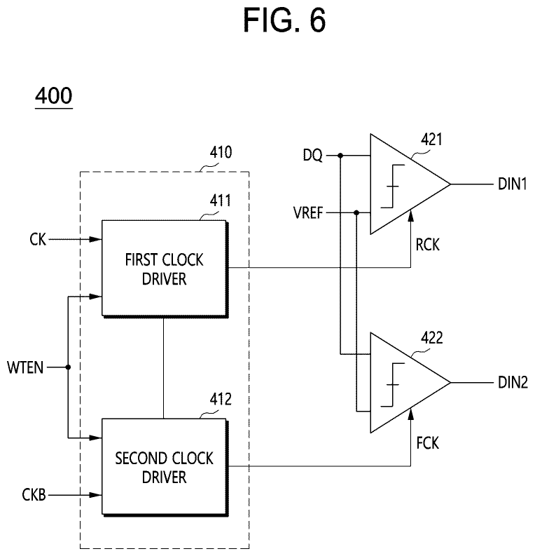

FIG. 6 is a diagram illustrating a configuration of a semiconductor apparatus 400 according to an embodiment of the present disclosure. Referring to FIG. 6, the semiconductor apparatus 400 may receive a data signal DQ in synchronization with a half-rate clock signal. The semiconductor apparatus 400 may receive the data signal DQ in synchronization with a first input clock signal CK and a second input clock signal CKB to generate a first internal data signal DIN1 and a second internal data signal DIN2. The second input clock signal CKB may have a lagging phase of 180 degrees relative to the first input clock signal CK. The semiconductor apparatus 400 may generate the first internal data signal DIN1 from the data signal DQ based on the first input clock signal CK and may generate the second internal data signal DIN2 from the data signal DQ based on the second input clock signal CKB.

The semiconductor apparatus 400 may include a clock buffer circuit 410, a first data receiver 421, and a second data receiver 422. The clock buffer circuit 410 may receive the first and second input clock signals CK and CKB to generate a first output clock signal RCK and a second output clock signal FCK. The clock buffer circuit 410 may buffer, drive, and/or repeat the first input clock signal CK to generate the first output clock signal RCK and may buffer, drive, and/or repeat the second input clock signal CKB to generate the second output clock signal FCK. The clock buffer circuit 410 may receive an enable signal WTEN and may be power-gated by the enable signal WTEN. When the enable signal WTEN is enabled, the clock buffer circuit 410 may be enabled and may generate the first and second output clock signals RCK and FCK from the first and second input clock signals CK and CKB. The operation of the semiconductor apparatus 400 receiving the data signal DQ may be a write operation, and the enable signal WTEN may be generated from a control signal related with the write operation. In an embodiment, the operation of the semiconductor apparatus 400 receiving the data signal DQ may be a read operation, and the enable signal WTEN may be generated from a control signal related with the read operation. The clock buffer circuit 410 may include a first clock driver 411 and a second clock driver 412. The first clock driver 411 may receive the first input clock signal CK and the enable signal WTEN to generate the first output clock signal RCK. The second clock driver 412 may receive the second input clock signal CKB and the enable signal WTEN to generate the second output clock signal FCK. The first clock driver 411 may include a first virtual node, and the second clock driver 412 may include a second virtual node. The first virtual node and the second virtual node may be electrically connected to each other. One of the clock buffer circuits 100, 200, and 300 as shown in FIGS. 1, 2, and 4 may be applied as the clock buffer circuit 410.

The first data receiver 421 may receive the data signal DQ and the first output clock signal RCK. The first data receiver 421 may generate the first internal data signal DIN1 from the data signal DQ in synchronization with the first output clock signal RCK. The first data receiver 421 may further receive a reference voltage VREF. The reference voltage VREF may have a voltage level corresponding to a middle of a range over which the data signal DQ swings. The first data receiver 421 may generate the first internal data signal DIN1 by comparing voltage levels of the data signal DQ and the reference voltage VREF. The second data receiver 422 may receive the data signal DQ and the second output clock signal FCK. The second data receiver 422 may generate the second internal data signal DIN2 from the data signal DQ in synchronization with the second output clock signal FCK. The second data receiver 422 may further receive the reference voltage VREF. The second data receiver 422 may generate the second internal data signal DIN2 by comparing voltage levels of the data signal DQ and the reference voltage VREF.

Because the first and second data receivers 421 and 422 receive the data signal DQ in synchronization with the first and second output clock signals RCK and FCK, the effective window and/or duration of the first and second internal data signals DIN1 and DIN2 may change depending on the slew rate of the first and second output clock signals

RCK and FCK. When the slew rate of the first and second output clock signals RCK and FCK is decreased, the effective window of the first and second internal data signals DIN1 and DIN2 may be decreased, and when the frequency of the first and second input clock signals CK and CKB or the first and second output clock signals RCK and FCK is increased, the effective window of the first and second internal data signals DIN1 and DIN2 may be further decreased. When the effective window of the first and second internal data signals DIN1 and DIN2 is decreased, operating margin of other internal circuits receiving the first and second internal data signals DIN1 and DIN2 may be decreased, causing malfunctions. The clock buffer circuit 410 may increase the slew rate of the first and second output clock signals RCK and FCK to increase the effective window of the first and second internal data signals DIN1 and DIN2 and may mitigate the malfunction of the semiconductor apparatus 400.

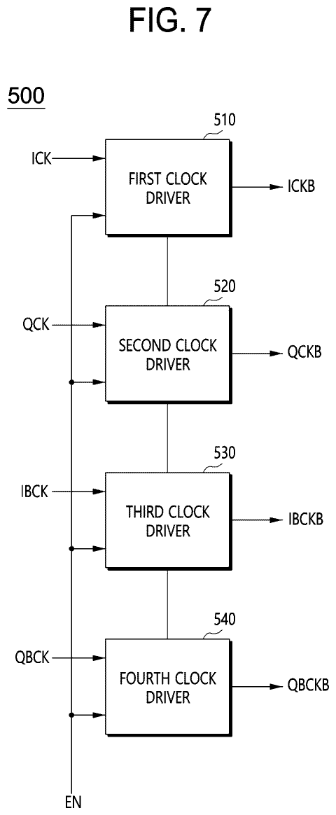

FIG. 7 is a diagram illustrating a configuration of a clock buffer circuit 500 according to an embodiment of the present disclosure. Referring to FIG. 7, the clock buffer circuit 500 may receive a quarter-rate clock signal. The clock buffer circuit 500 may receive a first input clock signal ICK, a second input clock signal QCK, a third input clock signal IBCK, and a fourth input clock signal QBCK to generate a first output clock signal ICKB, a second output clock signal QCKB, a third output clock signal IBCKB, and a fourth output clock signal QBCKB. The clock buffer circuit 500 may buffer, drive, and/or repeat the first to fourth input clock signals ICK, QCK, IBCK, and QBCK to generate the first to fourth output clock signals ICKB, QCKB, IBCKB, and QBCKB. The clock buffer circuit 500 may buffer, drive, and/or repeat the first input clock signal ICK to generate the first output clock signal ICKB and may buffer, drive, and/or repeat the second input clock signal QCK to generate the second output clock signal QCKB. The clock buffer circuit 500 may buffer, drive, and/or repeat the third input clock signal IBCK to generate the third output clock signal IBCKB and may buffer, drive, and/or repeat the fourth input clock signal QBCK to generate the fourth output clock signal QBCKB. The first to fourth input clock signals ICK, QCK, IBCK, and QBCK may have a phase difference of 90 degrees when compared sequentially. The first input clock signal ICK may have a leading phase of 90 degrees relative to the second input clock signal QCK, and the second input clock signal QCK may have a leading phase of 90 degrees relative to the third input clock signal IBCK. The third input clock signal IBCK may have a leading phase of 90 degrees relative to the fourth input clock signal QBCK, and the fourth input clock signal QBCK may have a leading phase of 90 degrees relative to the first input clock signal ICK. The phase relationship between the first to fourth output clock signals ICKB, QCKB, IBCKB, and QBCKB may be substantially the same as the phase relationship between the first to fourth input clock signals ICK, QCK, IBCK, and QBCK.

The clock buffer circuit 500 may further receive an enable signal EN. The enable signal EN may selectively enable the clock buffer circuit 500 by power-gating the clock buffer circuit 500. When the enable signal EN is enabled, the clock buffer circuit 500 may be activated and may generate the first to fourth output clock signals ICKB, QCKB, IBCKB, and QBCKB from the first to fourth input clock signals ICK, QCK, IBCK, and QBCK. When the enable signal EN is disabled, the clock buffer circuit 500 may be disabled and might not generate the first to fourth output clock signals ICKB, QCKB, IBCKB, and QBCKB. The clock buffer circuit 500 may be power-gated by the enable signal EN to mitigate the decrease in the slew rate of the first to fourth output clock signals ICKB, QCKB, IBCKB, and QBCKB. The clock buffer circuit 500 may improve the slew rate of the first to fourth output clock signals ICKB, QCKB, IBCKB, and QBCKB. For example, the clock buffer circuit 500 may decrease falling times of the first to fourth output clock signals ICKB, QCKB, IBCKB, and QBCKB and may steepen the transition slopes of the falling edges. In an embodiment, the clock buffer circuit 500 may decrease rising times of the first to fourth output clock signals ICKB, QCKB, IBCKB, and QBCKB and may steepen the transition slopes of the rising edges.

The clock buffer circuit 500 may include a first clock driver 510, a second clock driver 520, a third clock driver 530, and a fourth clock driver 540. The first clock driver 510 may receive the first input clock signal ICK and the enable signal EN to generate the first output clock signal ICKB. When the enable signal EN is enabled, the first clock driver 510 may buffer, drive, and/or repeat the first input clock signal ICK to generate the first output clock signal ICKB. When the enable signal EN is disabled, the first clock driver 510 may be disabled and might not generate the first output clock signal ICKB from the first input clock signal ICK.

The second clock driver 520 may receive the second input clock signal QCK and the enable signal EN to generate the second output clock signal QCKB. When the enable signal EN is enabled, the second clock driver 520 may buffer, drive, and/or repeat the second input clock signal QCK to generate the second output clock signal QCKB.

When the enable signal EN is disabled, the second clock driver 520 may be disabled and might not generate the second output clock signal QCKB from the second input clock signal QCK.

The third clock driver 530 may receive the third input clock signal IBCK and the enable signal EN to generate the third output clock signal IBCKB. When the enable signal EN is enabled, the third clock driver 530 may buffer, drive, and/or repeat the third input clock signal IBCK to generate the third output clock signal IBCKB. When the enable signal EN is disabled, the third clock driver 530 may be disabled and might not generate the third output clock signal IBCKB from the third input clock signal IBCK.

The fourth clock driver 540 may receive the fourth input clock signal QBCK and the enable signal EN to generate the fourth output clock signal QBCKB. When the enable signal EN is enabled, the fourth clock driver 540 may buffer, drive, and/or repeat the fourth input clock signal QBCK to generate the fourth output clock signal QBCKB. When the enable signal EN is disabled, the fourth clock driver 540 may be disabled and might not generate the fourth output clock signal QBCKB from the fourth input clock signal QBCK.

The first to fourth clock drivers 510, 520, 530, and 540 may include any driver circuit capable of buffering, driving and/or repeating a received input clock signal. The first to fourth clock drivers 510, 520, 530, and 540 may have substantially the same structure. Each of the first to fourth clock drivers 510, 520, 530, and 540 may include two transistors connected in series. The two transistors of the first to fourth clock drivers 510, 520, 530, and 540 may be of the same type of transistor. A node between the two transistors of the first clock driver 510, a node between the two transistors of the second clock driver 520, a node between the two transistors of the third clock driver 530, and a node between the two transistors of the fourth clock driver 540 may be electrically connected in common. The node between the two transistors of the first clock driver 510 may be a first virtual node. The node between the two transistors of the second clock driver 520 may be a second virtual node. The node between the two transistors of the third clock driver 530 may be a third virtual node. The node between the two transistors of the fourth clock driver 540 may be a fourth virtual node. The two transistors of the first clock driver 510 may receive the first input clock signal ICK and the enable signal EN, respectively. The two transistors of the second clock driver 520 may receive the second input clock signal QCK and the enable signal EN, respectively. The two transistors of the third clock driver 530 may receive the third input clock signal IBCK and the enable signal EN, respectively. The two transistors of the fourth clock driver 540 may receive the fourth input clock signal QBCK and the enable signal EN, respectively.

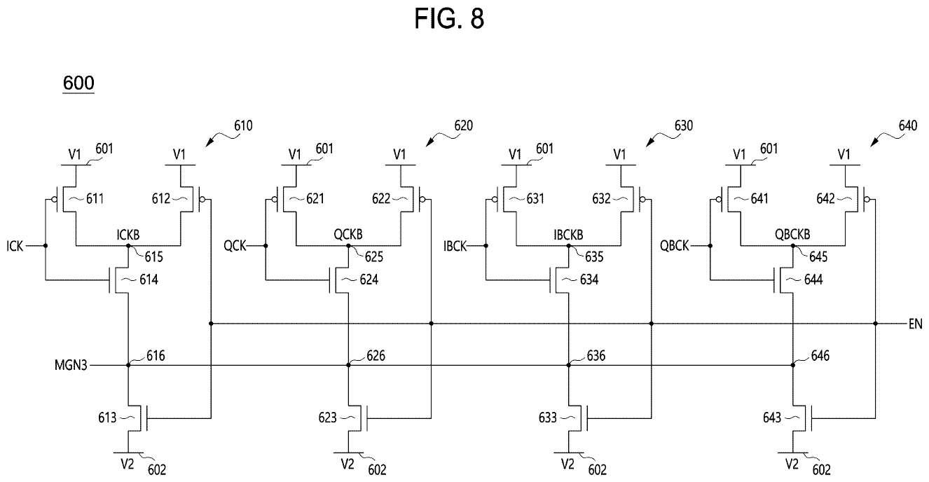

FIG. 8 is a circuit diagram illustrating a configuration of a clock buffer circuit 600 according to an embodiment of the present disclosure. Referring to FIG. 8, the clock buffer circuit 600 may include a first clock driver 610, a second clock driver 620, a third clock driver 630, and a fourth clock driver 640, and the first to fourth clock drivers 610, 620, 630, and 640 may each include a two-input NAND gate. The first to fourth clock drivers 610, 620, 630, and 640 may be applied as the first to fourth clock drivers 510, 520, 530, and 540 as shown in FIG. 7, respectively. The first clock driver 610 may receive the first input clock signal ICK and the enable signal EN to generate the first output clock signal ICKB. The second clock driver 620 may receive the second input clock signal QCK and the enable signal EN to generate the second output clock signal QCKB. The third clock driver 630 may receive the third input clock signal IBCK and the enable signal EN to generate the third output clock signal IBCKB. The fourth clock driver 640 may receive the fourth input clock signal QBCK and the enable signal EN to generate the fourth output clock signal QBCKB. The first clock driver 610 may include a first virtual ground node 616, and the second clock driver 620 may include a second virtual ground node 626. The third clock driver 630 may include a third virtual ground node 636, and the fourth clock driver 640 may include a fourth virtual ground node 646. The first clock driver 610 may include two transistors connected in series, receiving the first input clock signal ICK and the enable signal EN, respectively. The two transistors may be NMOS transistors. A node between the two transistors may be the first virtual ground node 616. The second clock driver 620 may include two transistors connected in series, receiving the second input clock signal QCK and the enable signal EN, respectively. The two transistors may be NMOS transistors. A node between the two transistors may be the second virtual ground node 626. The third clock driver 630 may include two transistors connected in series, receiving the third input clock signal IBCK and the enable signal EN, respectively. The two transistors may be NMOS transistors. A node between the two transistors may be the third virtual ground node 636. The fourth clock driver 640 may include two transistors connected in series, receiving the fourth input clock signal QBCK and the enable signal EN, respectively. The two transistors may be NMOS transistors. A node between the four transistors may be the fourth virtual ground node 646. The first to fourth virtual ground nodes 616, 626, 636, and 646 may be electrically connected in common.

The first clock driver 610 may include a first transistor 611, a second transistor 612, a third transistor 613, and a fourth transistor 614. The first and second transistors 611 and 612 may be PMOS transistors, and the third and fourth transistors 613 and 614 may be NMOS transistors. The first and second transistors 611 and 612 may be electrically connected in parallel between a first voltage terminal 601 to which the first voltage V1 is supplied and a first output node 615. The first output clock signal ICKB may be output from the first output node 615. A gate of the first transistor 611 may receive the first input clock signal ICK, a source of the first transistor 611 may be electrically connected to the first voltage terminal 601, and a drain of the first transistor 611 may be electrically connected to the first output node 615. A gate of the second transistor 612 may receive the enable signal EN, a source of the second transistor 612 may be electrically connected to the first voltage terminal 601, and a drain of the second transistor 612 may be electrically connected to the first output node 615. The third and fourth transistors 613 and 614 may be connected in series between the first output node 615 and a second voltage terminal 602 to which the second voltage V2 is supplied. A gate of the third transistor 613 may receive the enable signal EN, a drain of the third transistor 613 may be electrically connected to the first virtual ground node 616, and a source of the third transistor 613 may be electrically connected to the second voltage terminal 602. A gate of the fourth transistor 614 may receive the first input clock signal ICK, a drain of the fourth transistor 614 may be electrically connected to the first output node 615, and a source of the fourth transistor 614 may be electrically connected to the first virtual ground node 616.

The second clock driver 620 may include a fifth transistor 621, a sixth transistor 622, a seventh transistor 623, and an eighth transistor 624. The fifth and sixth transistors 621 and 622 may be PMOS transistors, and the seventh and eighth transistors 623 and 624 may be NMOS transistors. The fifth and sixth transistors 621 and 622 may be electrically connected in parallel between the first voltage terminal 601 and a second output node 625. The second output clock signal QCKB may be output from the second output node 625. A gate of the fifth transistor 621 may receive the second input clock signal QCK, a source of the fifth transistor 621 may be electrically connected to the first voltage terminal 601, and a drain of the fifth transistor 621 may be electrically connected to the second output node 625. A gate of the sixth transistor 622 may receive the enable signal EN, a source of the sixth transistor 622 may be electrically connected to the first voltage terminal 601, and a drain of the sixth transistor 622 may be electrically connected to the second output node 625. The seventh and eighth transistors 623 and 624 may be connected in series between the second output node 625 and the second voltage terminal 602. A gate of the seventh transistor 623 may receive the enable signal EN, a drain of the seventh transistor 623 may be electrically connected to the second virtual ground node 626, and a source of the seventh transistor 623 may be electrically connected to the second voltage terminal 602. A gate of the eighth transistor 624 may receive the second input clock signal QCK, a drain of the eighth transistor 624 may be electrically connected to the second output node 625, and a source of the eighth transistor 624 may be electrically connected to the second virtual ground node 626. The second virtual ground node 626 may be electrically connected to the first virtual ground node 616.

The third clock driver 630 may include a ninth transistor 631, a tenth transistor 632, an eleventh transistor 633, and a twelfth transistor 634. The ninth and tenth transistors 631 and 632 may be PMOS transistors, and the eleventh and twelfth transistors 633 and 634 may be NMOS transistors. The ninth and tenth transistors 631 and 632 may be electrically connected in parallel between the first voltage terminal 601 and a third output node 635. The third output clock signal IBCKB may be output from the third output node 635. A gate of the ninth transistor 631 may receive the third input clock signal IBCK, a source of the ninth transistor 631 may be electrically connected to the first voltage terminal 601, and a drain of the ninth transistor 631 may be electrically connected to the third output node 635. A gate of the tenth transistor 632 may receive the enable signal EN, a source of the tenth transistor 632 may be electrically connected to the first voltage terminal 601, and a drain of the tenth transistor 632 may be electrically connected to the third output node 635. The eleventh and twelfth transistors 633 and 634 may be connected in series between the third output node 635 and the second voltage terminal 602. A gate of the eleventh transistor 633 may receive the enable signal EN, a drain of the eleventh transistor 633 may be electrically connected to the third virtual ground node 636, and a source of the eleventh transistor 633 may be electrically connected to the second voltage terminal 602. A gate of the twelfth transistor 634 may receive the third input clock signal IBCK, a drain of the twelfth transistor 634 may be electrically connected to the third output node 635, and a source of the twelfth transistor 634 may be electrically connected to the third virtual ground node 636. The third virtual ground node 636 may be electrically connected in common with the first and second virtual ground nodes 616 and 626.

The fourth clock driver 640 may include a thirteenth transistor 641, a fourteenth transistor 642, a fifteenth transistor 643, and a sixteenth transistor 644. The thirteenth and fourteenth transistors 641 and 642 may be PMOS transistors, and the fifteenth and sixteenth transistors 643 and 644 may be NMOS transistors. The thirteenth and fourteenth transistors 641 and 642 may be electrically connected in parallel between the first voltage terminal 601 and a fourth output node 645. The fourth output clock signal QBCKB may be output from the fourth output node 645. A gate of the thirteenth transistor 641 may receive the fourth input clock signal QBCK, a source of the thirteenth transistor 641 may be electrically connected to the first voltage terminal 601, and a drain of the thirteenth transistor 641 may be electrically connected to the fourth output node 645. A gate of the fourteenth transistor 642 may receive the enable signal EN, a source of the fourteenth transistor 642 may be electrically connected to the first voltage terminal 601, and a drain of the fourteenth transistor 642 may be electrically connected to the fourth output node 645. The fifteenth and sixteenth transistors 643 and 644 may be connected in series between the fourth output node 645 and the second voltage terminal 602. A gate of the fifteenth transistor 643 may receive the enable signal EN, a drain of the fifteenth transistor 643 may be electrically connected to the fourth virtual ground node 646, and a source of the fifteenth transistor 643 may be electrically connected to the second voltage terminal 602. A gate of the sixteenth transistor 644 may receive the fourth input clock signal QBCK, a drain of the sixteenth transistor 644 may be electrically connected to the fourth output node 645, and a source of the sixteenth transistor 644 may be electrically connected to the fourth virtual ground node 646. The fourth virtual ground node 646 may be electrically connected in common with the first to third virtual ground nodes 616, 626, and 636, and the first to fourth virtual ground nodes 616, 626, 636, and 646 may be a single merge node MGN3. By the common connection of the first to fourth virtual ground nodes 616, 626, 636, and 646, the decrease in the slew rate of the first to fourth output clock signals ICKB, QCKB, IBCKB, and QBCKB may be mitigated or avoided.

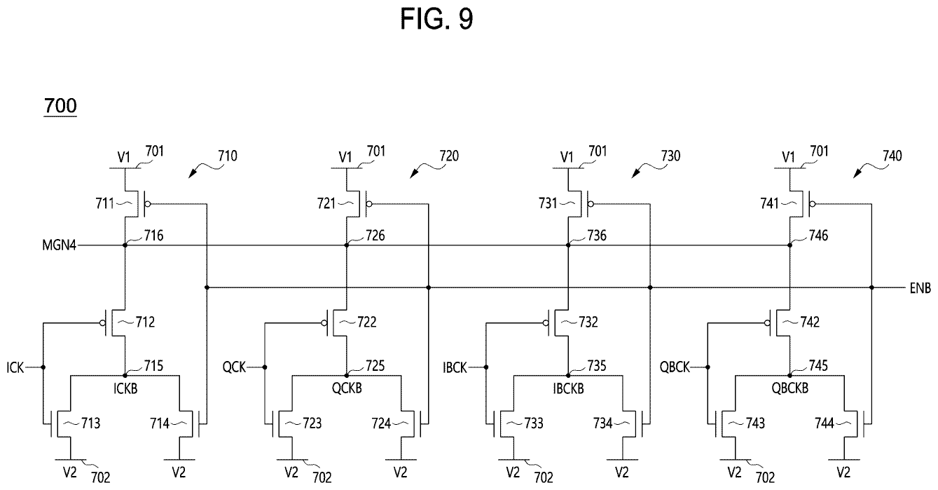

FIG. 9 is a diagram illustrating a configuration of a clock buffer circuit 700 according to an embodiment of the present disclosure. Referring to FIG. 9, the clock buffer circuit 700 may include a first clock driver 710, a second clock driver 720, a third clock driver 730, and a fourth clock driver 740, and each of the first to fourth clock drivers 710, 720, 730, and 740 may include a two-input NOR gate. The first to fourth clock drivers 710, 720, 730, and 740 may be applied as the first to fourth clock drivers 510, 520, 530, and 540 as shown in FIG. 7, respectively. The first clock driver 710 may receive the first input clock signal ICK and the enable signal ENB to generate the first output clock signal ICKB. The second clock driver 720 may receive the second input clock signal QCK and the enable signal ENB to generate the second output clock signal QCKB. The third clock driver 730 may receive the third input clock signal IBCK and the enable signal ENB to generate the third output clock signal IBCKB. The fourth clock driver 740 may receive the fourth input clock signal QBCK and the enable signal ENB to generate the fourth output clock signal QBCKB. The first clock driver 710 may include a first virtual supply node 716, and the second clock driver 720 may include a second virtual supply node 726. The third clock driver 730 may include a third virtual supply node 736, and the fourth clock driver 740 may include a fourth virtual supply node 746. The first clock driver 710 may include two transistors connected in series, receiving the first input clock signal ICK and the enable signal ENB, respectively. The two transistors may be PMOS transistors. A node between the two transistors may be the first virtual supply node 716. The second clock driver 720 may include two transistors connected in series, receiving the second input clock signal QCK and the enable signal ENB, respectively. The two transistors may be PMOS transistors. A node between the two transistors may be the second virtual supply node 726. The third clock driver 730 may include two transistors connected in series, receiving the third input clock signal IBCK and the enable signal ENB, respectively. The two transistors may be PMOS transistors. A node between the two transistors may be the third virtual supply node 736. The fourth clock driver 740 may include two transistors connected in series, receiving the fourth input clock signal QBCK and the enable signal ENB, respectively. The two transistors may be PMOS transistors. A node between the two transistors may be the fourth virtual supply node 746. The first to fourth virtual supply nodes 716, 726, 736, and 746 may be electrically connected in common.

The first clock driver 710 may include a first transistor 711, a second transistor 712, a third transistor 713, and a fourth transistor 714. The first and second transistors 711 and 712 may be PMOS transistors, and the third and fourth transistors 713 and 714 may be NMOS transistors. The first and second transistors 711 and 712 may be connected in series between a first voltage terminal 701 to which the first voltage V1 is supplied and a first output node 715. The first output clock signal ICKB may be output from the first output node 715. A gate of the first transistor 711 may receive the enable signal ENB, a source of the first transistor 711 may be electrically connected to the first voltage terminal 701, and a drain of the first transistor 711 may be electrically connected to the first virtual supply node 716. A gate of the second transistor 712 may receive the first input clock signal ICK, a source of the second transistor 712 may be electrically connected to the first virtual supply node 716, and a drain of the second transistor 712 may be electrically connected to the first output node 715. The third and fourth transistors 713 and 714 may be electrically connected in parallel between the first output node 715 and a second voltage terminal 702 to which the second voltage V2 is supplied. A gate of the third transistor 713 may receive the first input clock signal ICK, a drain of the third transistor 713 may be electrically connected to the first output node 715, and a source of the third transistor 713 may be electrically connected to the second voltage terminal 702. A gate of the fourth transistor 714 may receive the enable signal ENB, a drain of the fourth transistor 714 may be electrically connected to the first output node 715, and a source of the fourth transistor 714 may be electrically connected to the second voltage terminal 702.

The second clock driver 720 may include a fifth transistor 721, a sixth transistor 722, a seventh transistor 723, and an eighth transistor 724. The fifth and sixth transistors 721 and 722 may be PMOS transistors, and the seventh and eighth transistors 723 and 724 may be NMOS transistors. The fifth and sixth transistors 721 and 722 may be connected in series between the first voltage terminal 701 and a second output node 725. The second output clock signal QCKB may be output from the second output node 725. A gate of the fifth transistor 721 may receive the enable signal ENB, a source of the fifth transistor 721 may be electrically connected to the first voltage terminal 701, and a drain of the fifth transistor 721 may be electrically connected to the second virtual supply node 726. A gate of the sixth transistor 722 may receive the second input clock signal QCK, a source of the sixth transistor 722 may be electrically connected to the second virtual supply node 726, and a drain of the sixth transistor 722 may be electrically connected to the second output node 725. The seventh and eighth transistors 723 and 724 may be electrically connected in parallel between the second output node 725 and the second voltage terminal 702. A gate of the seventh transistor 723 may receive the second input clock signal QCK, a drain of the seventh transistor 723 may be electrically connected to the second output node 725, and a source of the seventh transistor 723 may be electrically connected to the second voltage terminal 702. A gate of the eighth transistor 724 may receive the enable signal ENB, a drain of the eighth transistor 724 may be electrically connected to the second output node 725, and a source of the eighth transistor 724 may be electrically connected to the second voltage terminal 702. The second virtual supply node 726 may be electrically connected to the first virtual supply node 716.

The third clock driver 730 may include a ninth transistor 731, a tenth transistor 732, an eleventh transistor 733, and a twelfth transistor 734. The ninth and tenth transistors 731 and 732 may be PMOS transistors, and the eleventh and twelfth transistors 733 and 734 may be NMOS transistors. The ninth and tenth transistors 731 and 732 may be connected in series between the first voltage terminal 701 and a third output node 735. The third output clock signal IBCKB may be output from the third output node 735. A gate of the ninth transistor 731 may receive the enable signal ENB, a source of the ninth transistor 731 may be electrically connected to the first voltage terminal 701, and a drain of the ninth transistor 731 may be electrically connected to the third virtual supply node 736. A gate of the tenth transistor 732 may receive the third input clock signal IBCK, a source of the tenth transistor 732 may be electrically connected to the third virtual supply node 736, and a drain of the tenth transistor 732 may be electrically connected to the third output node 735. The eleventh and twelfth transistors 733 and 734 may be electrically connected in parallel between the third output node 735 and the second voltage terminal 702. A gate of the eleventh transistor 733 may receive the third input clock signal IBCK, a drain of the eleventh transistor 733 may be electrically connected to the third output node 735, and a source of the eleventh transistor 733 may be electrically connected to the second voltage terminal 702. A gate of the twelfth transistor 734 may receive the enable signal ENB, a drain of the twelfth transistor 734 may be electrically connected to the third output node 735, and a source of the twelfth transistor 734 may be electrically connected to the second voltage terminal 702. The third virtual supply node 736 may be electrically connected in common with the first and second virtual supply nodes 716 and 726.

The fourth clock driver 740 may include a thirteenth transistor 741, a fourteenth transistor 742, a fifteenth transistor 743, and a sixteenth transistor 744. The thirteenth and fourteenth transistors 741 and 742 may be PMOS transistors, and the fifteenth and sixteenth transistors 743 and 744 may be NMOS transistors. The thirteenth and fourteenth transistors 741 and 742 may be connected in series between the first voltage terminal 701 and a fourth output node 745. The fourth output clock signal QBCKB may be output from the fourth output node 745. A gate of the thirteenth transistor 741 may receive the enable signal ENB, a source of the thirteenth transistor 741 may be electrically connected to the first voltage terminal 701, and a drain of the thirteenth transistor 741 may be electrically connected to the fourth virtual supply node 746. A gate of the fourteenth transistor 742 may receive the fourth input clock signal QBCK, a source of the fourteenth transistor 742 may be electrically connected to the fourth virtual supply node 746, and a drain of the fourteenth transistor 742 may be electrically connected to the fourth output node 745. The fifteenth and sixteenth transistors 743 and 744 may be electrically connected in parallel between the fourth output node 745 and the second voltage terminal 702. A gate of the fifteenth transistor 743 may receive the fourth input clock signal QBCK, a drain of the fifteenth transistor 743 may be electrically connected to the fourth output node 745, and a source of the fifteenth transistor 743 may be electrically connected to the second voltage terminal 702. A gate of the sixteenth transistor 744 may receive the enable signal ENB, a drain of the sixteenth transistor 744 may be electrically connected to the fourth output node 745, and a source of the sixteenth transistor 744 may be electrically connected to the second voltage terminal 702. The fourth virtual supply node 746 may be electrically connected in common with the first to third virtual supply nodes 716, 726, and 736, and the first to fourth virtual supply nodes 716, 726, 736, and 746 may be one merge node MGN4. By having the first to fourth virtual supply nodes 716, 726, 736, and 746 in common connection, the decrease in the slew rate of the first to fourth output clock signals ICKB, QCKB, IBCKB, and QBCKB may be mitigated or avoided.

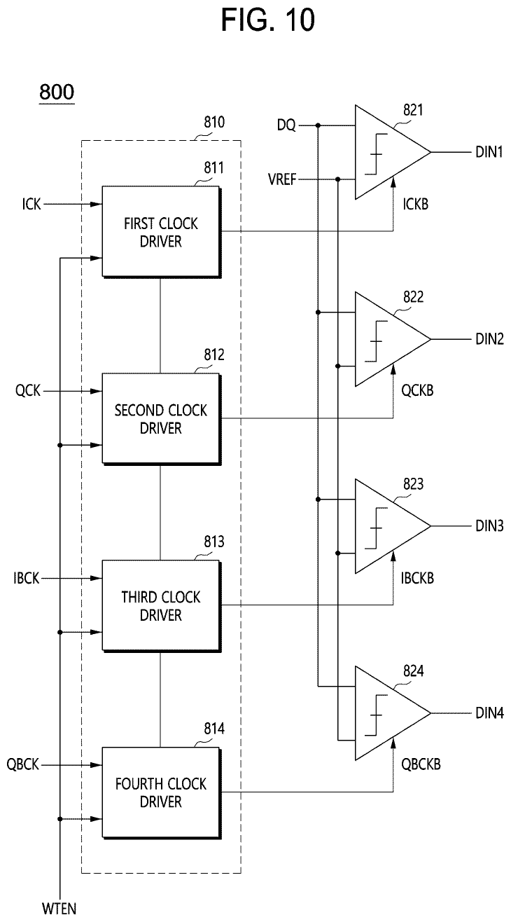

FIG. 10 is a diagram illustrating a configuration of a semiconductor apparatus 800 according to an embodiment of the present disclosure. Referring to FIG. 10, the semiconductor apparatus 800 may receive a data signal DQ in synchronization with a quarter-rate clock signal. The semiconductor apparatus 800 may receive the data signal DQ in synchronization with a first input clock signal ICK, a second input clock signal QCK, a third input clock signal ICKB, and a fourth input clock signal QCKB to generate a first internal data signal DIN1, a second internal data signal DIN2, a third internal data signal DIN3, and a fourth internal data signal DIN4. The semiconductor apparatus 800 may generate the first internal data signal DIN1 from the data signal DQ based on the first input clock signal ICK and may generate the second internal data signal DIN2 from the data signal DQ based on the second input clock signal QCK. The semiconductor apparatus 800 may generate the third internal data signal DIN3 from the data signal DQ based on the third input clock signal IBCK and may generate the fourth internal data signal DIN4 from the data signal DQ based on the fourth input clock signal QBCK.

The semiconductor apparatus 800 may include a clock buffer circuit 810, a first data receiver 821, a second data receiver 822, a third data receiver 823, and a fourth data receiver 824. The clock buffer circuit 810 may receive the first to fourth input clock signals ICK, QCK, IBCK, and QBCK to generate a first output clock signal ICKB, a second output clock signal QCKB, a third output clock signal IBCKB, and a fourth output clock signal QBCKB. The clock buffer circuit 810 may buffer, drive, and/or repeat the first input clock signal ICK to generate the first output clock signal ICKB and may buffer, drive, and/or repeat the second input clock signal QCK to generate the second output clock signal QCKB. The clock buffer circuit 810 may buffer, drive, and/or repeat the third input clock signal IBCK to generate the third output clock signal IBCKB and may buffer, drive and/or repeat the fourth input clock signal QBCK to generate the fourth output clock signal QBCKB. The clock buffer circuit 810 may receive an enable signal WTEN and may be power-gated by the enable signal WTEN. When the enable signal WTEN is enabled, the clock buffer circuit 810 may be enabled and may generate the first to fourth output clock signals ICKB, QCKB, IBCKB, and QBCKB from the first to fourth input clock signals ICK, QCK, IBCK, and QBCK. The operation of the semiconductor apparatus 800 receiving the data signal DQ may be a write operation, and the enable signal WTEN may be generated from a control signal related with the write operation. In an embodiment, the operation of the semiconductor apparatus 800 receiving the data signal DQ may be a read operation, and the enable signal WTEN may be generated from a control signal related with the read operation. The clock buffer circuit 810 may include a first clock driver 811, a second clock driver 812, a third clock driver 813, and a fourth clock driver 814. The first clock driver 811 may receive the first input clock signal ICK and the enable signal WTEN to generate the first output clock signal ICKB. The second clock driver 812 may receive the second input clock signal QCK and the enable signal WTEN to generate the second output clock signal QCKB. The third clock driver 813 may receive the third input clock signal IBCK and the enable signal WTEN to generate the third output clock signal IBCKB. The fourth clock driver 814 may receive the fourth input clock signal QBCK and the enable signal WTEN to generate the fourth output clock signal QBCKB. The first clock driver 811 may include a first virtual node, and the second clock driver 812 may include a second virtual node. The third clock driver 813 may include a third virtual node, and the fourth clock driver 814 may include a fourth virtual node. The first to fourth virtual nodes may be electrically connected in common. Any one of the clock buffer circuits 500, 600, and 700, shown in FIGS. 7, 8, and 9, may be applied as the clock buffer circuit 810.

The first data receiver 821 may receive the data signal DQ and the first output clock signal ICKB. The first data receiver 821 may generate the first internal data signal DIN1 from the data signal DQ in synchronization with the first output clock signal ICKB. The first data receiver 821 may further receive a reference voltage VREF. The reference voltage VREF may have a voltage level corresponding to a middle of a range over which the data signal DQ swings. The first data receiver 821 may generate the first internal data signal DIN1 by comparing voltage levels of the data signal DQ and the reference voltage VREF. The second data receiver 822 may receive the data signal DQ and the second output clock signal QCKB. The second data receiver 822 may generate the second internal data signal DIN2 from the data signal DQ in synchronization with the second output clock signal QCKB. The second data receiver 822 may further receive the reference voltage VREF. The second data receiver 822 may generate the second internal data signal DIN2 by comparing voltage levels of the data signal DQ and the reference voltage VREF. The third data receiver 823 may receive the data signal DQ and the third output clock signal IBCKB. The third data receiver 823 may generate the third internal data signal DIN3 from the data signal DQ in synchronization with the third output clock signal IBCKB. The third data receiver 823 may further receive the reference voltage VREF. The third data receiver 823 may generate the third internal data signal DIN3 by comparing voltage levels of the data signal DQ and the reference voltage VREF. The fourth data receiver 824 may receive the data signal DQ and the fourth output clock signal QBCKB. The fourth data receiver 824 may generate the fourth internal data signal DIN4 from the data signal DQ in synchronization with the fourth output clock signal QBCKB. The fourth data receiver 824 may further receive the reference voltage VREF. The fourth data receiver 824 may generate the fourth internal data signal DIN4 by comparing voltage levels of the data signal DQ and the reference voltage VREF. The clock buffer circuit 810 may increase the slew rate of the first to fourth output clock signals ICKB, QCKB, IBCKB, and QBCKB to improve operating margin of the first to fourth data receivers 821, 822, 823, and 824 and may increase the effective window of the first to fourth internal data signals DIN1, DIN2, DIN3, and DIN4, thereby mitigating the occurrence of a malfunction in the semiconductor apparatus 800.

A person skilled in the art to which the present disclosure pertains can understand that the present disclosure may be carried out in other specific forms without changing its technical spirit or essential features. Therefore, it should be understood that the embodiments described above are illustrative in all aspects, not limitative. The scope of the present disclosure is defined by the claims to be described below rather than the detailed description, and it should be construed that the meaning and scope of the claims and all changes or modified forms derived from the equivalent concept thereof are included in the scope of the present disclosure.

What is claimed is:

1. A clock buffer circuit, comprising:
a first clock driver, including two transistors connected in series, configured to receive a first input clock signal and an enable signal to generate a first output clock signal, the two transistors of the first clock driver receiving the first input clock signal and the enable signal, respectively; and
a second clock driver, including two transistors connected in series, configured to receive a second input clock signal and the enable signal to generate a second output clock signal, the two transistors of the second clock driver receiving the second input clock signal and the enable signal, respectively,
wherein a node between the two transistors of the first clock driver and a node between the two transistors of the second clock driver are electrically connected.

2. The clock buffer circuit of claim 1, wherein the two transistors of the first clock driver and the two transistors of the second clock driver are each NMOS transistors.

3. The clock buffer circuit of claim 2, wherein the two transistors of the first clock driver are electrically connected between another transistor of the first clock driver and a voltage terminal to which a ground voltage is supplied, and
wherein the two transistors of the second clock driver are electrically connected between another transistor of the second clock driver and the voltage terminal to which the ground voltage is supplied.

4. The clock buffer circuit of claim 1, wherein the two transistors of the first clock driver and the two transistors of the second clock driver are each PMOS transistors.

5. The clock buffer circuit of claim 4, wherein the two transistors of the first clock driver are electrically connected between a voltage terminal to which a power supply voltage is supplied and another transistor of the first clock driver, and
wherein the two transistors of the second clock driver are electrically connected between the voltage terminal to which the power supply voltage is supplied and another transistor of the second clock driver.

6. A clock buffer circuit, comprising:
a first clock driver configured to receive a first input clock signal and an enable signal to generate a first output clock signal, the first clock driver including a first virtual ground node; and
a second clock driver configured to receive a second input clock signal and the enable signal to generate a second output clock signal, the second clock driver including a second virtual ground node,
wherein the first virtual ground node is electrically connected to the second virtual ground node.

7. The clock buffer circuit of claim 6, wherein the first and second clock drivers are each a NAND gate.

8. The clock buffer circuit of claim 6, wherein the first clock driver comprises:
a first transistor receiving the first input clock signal to electrically connect a first voltage terminal to a first output node, the first output clock signal being output from the first output node;
a second transistor receiving the enable signal to electrically connect the first voltage terminal to the first output node;
a third transistor receiving the first input clock signal to electrically connect the first output node to the first virtual ground node; and
a fourth transistor receiving the enable signal to electrically connect the first virtual ground node to a second voltage terminal.

9. The clock buffer circuit of claim 8, wherein the second clock driver comprises:
a fifth transistor receiving the second input clock signal to electrically connect the first voltage terminal to a second output node, the second output clock signal being output from the second output node;
a sixth transistor receiving the enable signal to electrically connect the first voltage terminal to the second output node;
a seventh transistor receiving the second input clock signal to electrically connect the second output node to the second virtual ground node; and
an eighth transistor receiving the enable signal to electrically connect the second virtual ground node to the second voltage terminal.

10. A clock buffer circuit, comprising:
a first clock driver configured to receive a first input clock signal and an enable signal to generate a first output clock signal, the first clock driver including a first virtual supply node; and
a second clock driver configured to receive a second input clock signal and the enable signal to generate a second output clock signal, the second clock driver including a second virtual supply node,
wherein the first virtual supply node is electrically connected to the second virtual supply node.

11. The clock buffer circuit of claim 10, wherein the first and second clock drivers are each a NOR gate.

12. The clock buffer circuit of claim 10, wherein the first clock driver comprises:
a first transistor receiving the enable signal to electrically connect a first voltage terminal to the first virtual supply node;
a second transistor receiving the first input clock signal to electrically connect the first virtual supply node to a first output node, the first output clock signal being output from the first output node;
a third transistor receiving the first input clock signal to electrically connect the first output node to a second voltage terminal; and
a fourth transistor receiving the enable signal to electrically connect the first output node to the second voltage terminal.

13. The clock buffer circuit of claim 12, wherein the second clock driver comprises:
a fifth transistor receiving the enable signal to electrically connect the first voltage terminal to the second virtual supply node;
a sixth transistor receiving the second input clock signal to electrically connect the second virtual supply node to a second output node, the second output clock signal being output from the second output node;
a seventh transistor receiving the second input clock signal to electrically connect the second output node to the second voltage terminal; and
an eighth transistor receiving the enable signal to electrically connect the second output node to the second voltage terminal.

14. A semiconductor apparatus, comprising:
a first clock driver configured to receive a first input clock signal and an enable signal to generate a first output clock signal, the first clock driver including a first virtual node;
a second clock driver configured to receive a second input clock signal and the enable signal to generate a second output clock signal, the second clock driver including a second virtual node electrically connected to the first virtual node;
a first data receiver configured to receive a data signal in synchronization with the first output clock signal to generate a first internal data signal; and
a second data receiver configured to receive the data signal in synchronization with the second output clock signal to generate a second internal data signal.

15. The semiconductor apparatus of claim 14, wherein the first and second clock drivers are each a NAND gate, and
wherein the first and second virtual nodes are each a virtual ground node.

16. The semiconductor apparatus of claim 14, wherein the first and second clock drivers are each a NOR gate, and
wherein the first and second virtual nodes are each a virtual supply node.

17. The semiconductor apparatus of claim 14, wherein the first clock driver comprises two transistors connected in series, receiving the first input clock signal and the enable signal, respectively, and
wherein the first virtual node is a node between the two transistors.

18. The semiconductor apparatus of claim 14, wherein the second clock driver comprises two transistors connected in series, receiving the second input clock signal and the enable signal, respectively, and
wherein the second virtual node is a node between the two transistors.

19. The semiconductor apparatus of claim 14, wherein the first and second data receivers each further receive a reference voltage and each compare the data signal with the reference voltage to generate the first and second internal data signals, respectively.
